(19) United States
(12) Patent Application Publication
(10) Pub. No.: US 2013/0001596 A1
(43) Pub. Date: Jan. 3, 2013

(54) DEPOSITION OF ESD PROTECTION ON PRINTED CIRCUIT BOARDS

(75) Inventors: Adam M. Scotch, Amesbury, MA (US); David W. Hamby, Andover, MA (US)

(73) Assignee: OSRAM SYLVANIA INC., Danvers, MA (US)

(21) Appl. No.: 13/170,276

(22) Filed: Jun. 28, 2011

(51) Int. Cl. H01L 33/08

(52) U.S. Cl. 257/88; 438/34; 257/659; 257/E33.055

(57) ABSTRACT

A method and apparatus for providing electro-static discharge (ESD) protection to light emitting diode (LED) systems on printed circuit boards (PCBs). Protection is provided by ESD diodes deposited on the PCBs configured as flexible substrates. Various deposition techniques are employed including chemical vapor deposition, pulsed laser deposition and atomic layer deposition.

### TECHNICAL FIELD

The present application relates generally to providing electrostatic discharge (ESD) protection on printed circuit boards, and, more particularly, to providing such protection in light emitting diode (LED) systems.

### BACKGROUND

Damage to electronic components resulting from electrostatic discharge can pose a serious problem for high technology companies. The financial cost of such damages can sometimes exceed ten percent of annual gross sales by some estimates and can affect productivity and product reliability across a broad spectrum of the electronics industry.

LEDs are one type of electronic component subject to damage by ESD. ESD damage can occur during manufacturing, handling, packaging or installation. Large numbers of LEDs are often aggregated onto modules to create lighting systems which require ESD protection. What is needed, therefore, is an ESD protection mechanism that can be incorporated into these modules with minimal impact on the complexity and cost of the manufacturing process while simultaneously providing a high degree of protection and reliability.

### BRIEF DESCRIPTION OF THE DRAWINGS

Reference should be made to the following detailed description which should be read in conjunction with the following figures, wherein like numerals represent like parts:

FIG. 1 diagrammatically illustrates one embodiment of an ESD protection circuit consistent with the present disclosure;

FIG. 2 diagrammatically illustrates one embodiment of an array of LEDs with ESD protection consistent with the present disclosure;

FIG. 3 diagrammatically illustrates another embodiment of an array of LEDs with ESD protection consistent with the present disclosure;

FIG. 4 is a block flow diagram illustrating one method consistent with the present disclosure; and

FIG. 5 diagrammatically illustrates a reel to reel manufacturing process for LED module fabrication consistent with the present disclosure.

### DETAILED DESCRIPTION

Light emitting diodes (LEDs), a type of optoelectronic device, are vulnerable to damage by electrostatic discharge (ESD). One method of protecting these devices is to place a reversed diode in parallel with a single LED, a string of LEDs or even an array of LEDs.

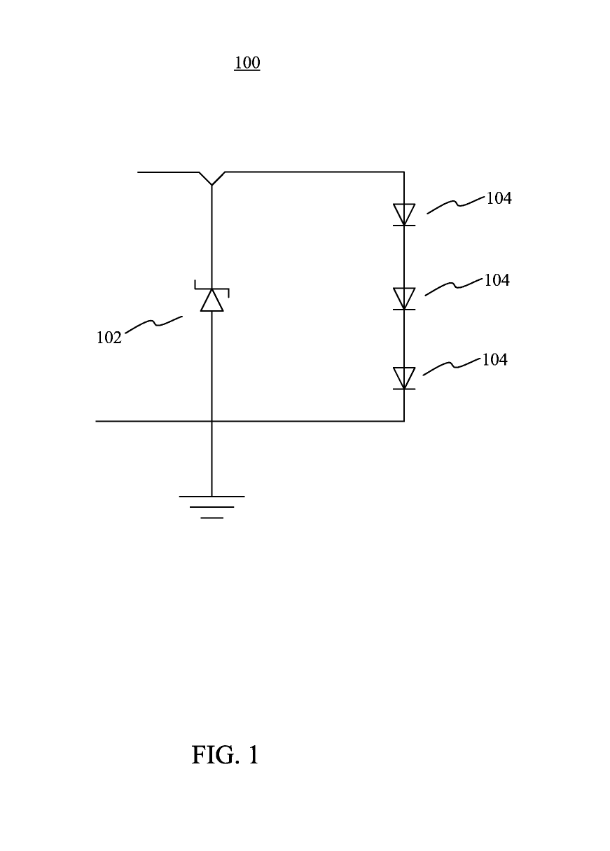

FIG. 1 diagrammatically illustrates one embodiment of an ESD protection circuit 100 consistent with the present disclosure. The illustrated circuit includes a string of LEDs 104 in parallel with a reversed zener diode 102 which protects the LEDs 104 from ESD damage. The zener diode 102 has a reverse breakdown voltage that is low enough to shunt damaging currents, caused by ESD, away from the LEDs. The degree of ESD protection provided by the diode 102 decreases, however, with distance from the LEDs 104. To maximize ESD protection and increase system reliability, each LED 104 may have a local ESD diode 102 in close proximity to the LED.

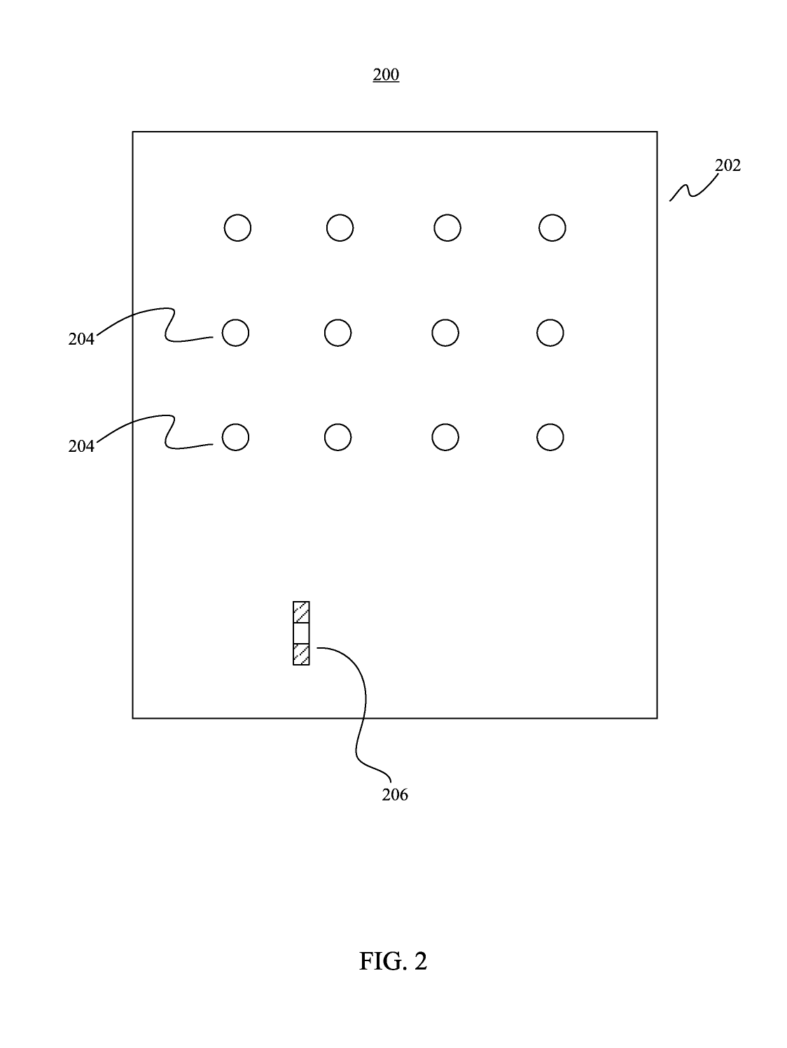

FIG. 2 diagrammatically illustrates one embodiment of an array of LEDs with ESD protection 200 consistent with the present disclosure. The illustration shows an LED module 202 which may be a printed circuit board (PCB). The module 202 comprises LEDs 204 arranged in a three by four array as one example configuration of a lighting system component. A single ESD protection diode 206 is provided on the module 202 as a surface mount (SMT) device. Typically only one or two SMT mounted ESD diodes 206 are provided on an LED module 202 due to the relatively large footprint and cost of the SMT mounted device as well as the additional burden on the OEM due to the solder reflow process.

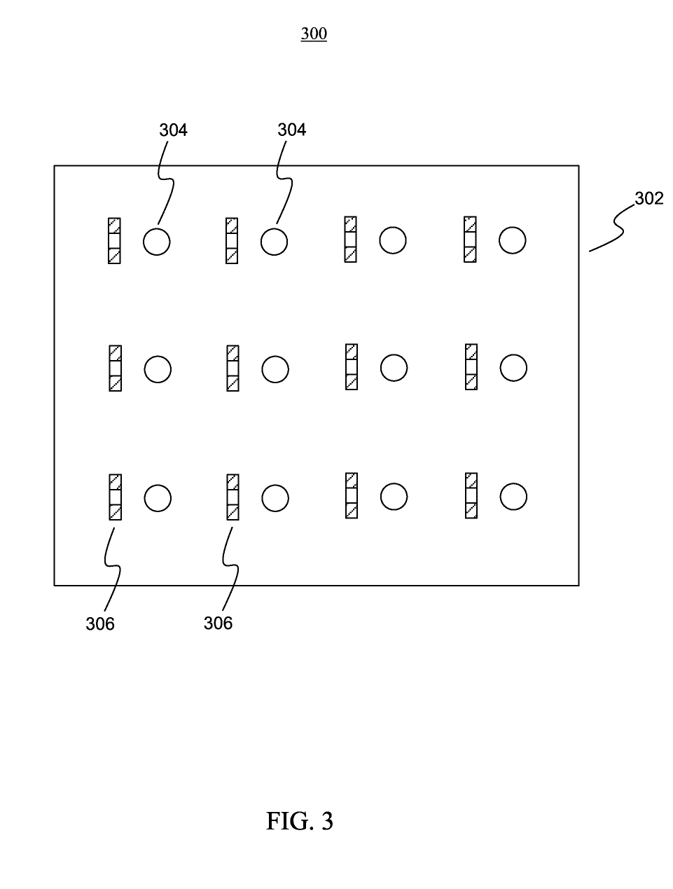

FIG. 3 diagrammatically illustrates another embodiment of an array of LEDs with ESD protection 300 consistent with the present disclosure. The illustration shows an LED module 302 which may be a PCB implemented as a flexible substrate. The module 302 comprises LEDs 304 arranged in a three by four array, as one example configuration of a lighting system component. An ESD protection diode 306 is provided for each LED 304, through a deposition or printing process which results in a significantly reduced cost and footprint compared to the SMT mounted approach previously described. The ability to deposit ESD diodes has been enabled by recent developments in conductive polymer technology. By providing more ESD diodes 306 and locating them closer to the LEDs 304, ESD protection and system reliability are significantly increased.

Directly depositing ESD diodes, in the form of conductive polymers, onto the flexible substrate PCB also simplifies the ability to handle minor modifications to the LED layout or module design after a PCB design has been finalized.

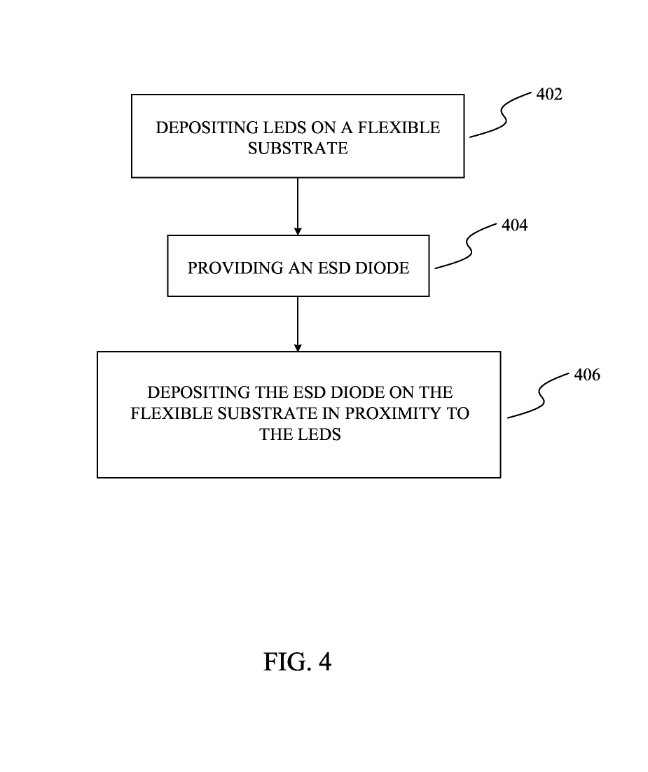

FIG. 4 is a block flow diagram illustrating one method consistent with the present disclosure. The illustrated method includes depositing LEDs on a flexible substrate 402, providing an ESD diode 404, and depositing the ESD diode on the flexible substrate in proximity to the LEDs 406. Various methods of deposition are possible. The deposition may use a process such as chemical vapor deposition, metalorganic chemical vapor deposition, pulsed laser deposition, atomic layer deposition, spatial atomic layer deposition, direct writing via positive displacement dispensing, ink-jet deposition or aerosol jetting deposition.

The ESD diodes may be deposited on the flexible substrate in a thin film array comprising a structure of multiple layers. As will be understood by those skilled in the art, each physical vapor deposition process includes a plurality of associated parameters whose nominal values may be selected and/or adjusted to yield a thin film structure with one or more desired properties. As used herein, use of the term “nominal” or “nominally” when referring to an amount means a designated or theoretical amount that may vary from the actual amount. For example, process parameters associated with pulsed laser deposition include temperature, deposition pressure, laser repetition rate, total number of laser pulses, and the gas environment to grow the films, e.g. N₂, H₂, Ar or forming gas. The nominal value(s) of one or more parameters chosen may depend on the substrate material, a desired thickness of the thin film structure and/or a desired surface characteristic (e.g., uniform or non-uniform) of the thin film structure. Nominal value(s) of the parameters may be adjusted during the deposition process to thereby change one or more characteristics of the thin film structure.

Providing the ability to deposit ESD diodes directly on a substrate allows the PCB designer to place as many ESD protection points as needed, thereby protecting all LEDs and electronic devices on the circuit.

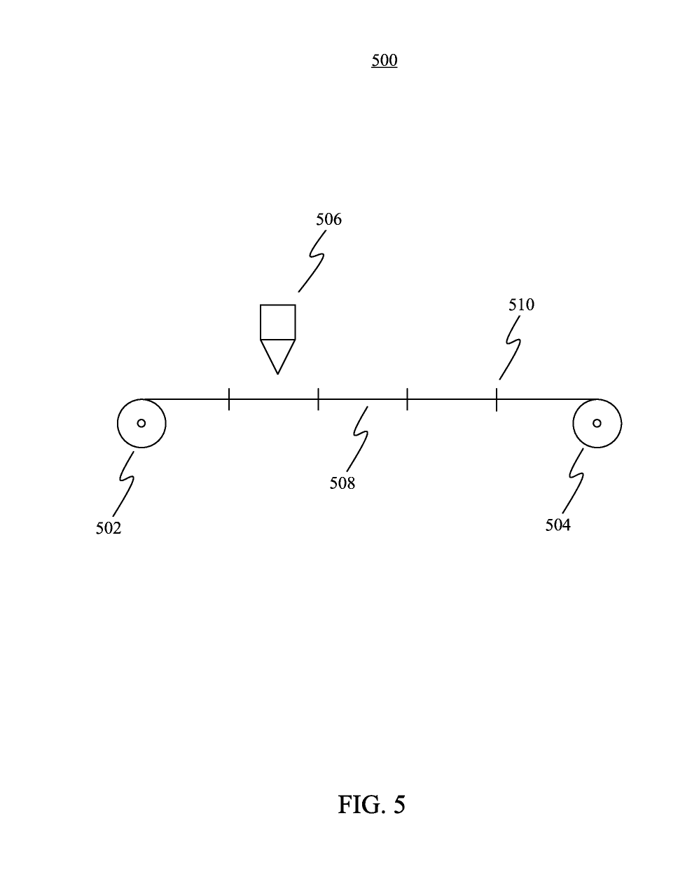

FIG. 5 diagrammatically illustrates a reel to reel manufacturing process 500 for LED module fabrication consistent with the present disclosure. The illustration shows an out feed spool or reel 502 and a take up spool or reel 504. This allows for an efficient reel to reel manufacturing process where a PCB, implemented as a flexible substrate 508, is unwound from out feed reel 502 and passed, in a continuous feed motion, under deposition device 506 to be subsequently rewound onto take up reel 504. Deposition device 506 deposits LEDs, ESD diodes and any other required components onto flexible substrate 508. Flexible substrate 508 may later be divided into sections along boundary lines 510 where each section makes up a lighting module comprising an array of LEDs, ESD diodes and associated components.

According to one aspect of the disclosure, there is provided a method of providing electro-static discharge (ESD) protection to a plurality of light emitting diodes (LEDs) wherein the plurality of LEDs are deposited on a flexible substrate, the method including: providing an ESD diode; and depositing the ESD diode on the flexible substrate in proximity to the plurality of LEDs. The deposition process may be a chemical vapor deposition, metalorganic chemical vapor deposition, pulsed laser deposition, atomic layer deposition, spatial atomic layer deposition, direct writing via positive displacement dispensing, ink-jet or aerosol jetting. The proximity of placement the ESD diode to the LED as well as the number of ESD diodes to be deposited may be determined by the degree of ESD protection required. The ESD diodes may be fabricated from conductive polymers.

According to another aspect of the disclosure, there is provided a light source including: a module comprising a flexible substrate; a plurality of light emitting diodes (LEDs) deposited on the module; and an electrostatic discharge (ESD) diode deposited on the module in proximity to the plurality of LEDs.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A method of providing electro-static discharge (ESD) protection to a plurality of light emitting diodes (LEDs) wherein said plurality of LEDs are deposited on a flexible substrate, said method comprising:
providing an ESD diode; and
depositing said ESD diode on said flexible substrate in proximity to said plurality of LEDs.

2. A method according to claim 1, wherein said ESD diode is deposited using a spatial atomic layer deposition process.

3. A method according to claim 1, wherein said ESD diode is deposited using a chemical vapor deposition process.

4. A method according to claim 1, wherein said ESD diode is deposited using a pulsed laser deposition process.

5. A method according to claim 1, wherein said ESD diode is deposited using a process selected from the group consisting of metalorganic chemical vapor deposition, atomic layer deposition, direct writing via positive displacement dispensing, ink-jet deposition and aerosol jetting deposition.

6. A method according to claim 1, wherein said proximity is determined based on a requirement for ESD protection reliability.

7. A method according to claim 1, wherein the number of said ESD diodes is determined based on a requirement for ESD protection reliability.

8. A method according to claim 1, wherein said ESD diode comprises a conductive polymer.

9. A light source comprising:
a module comprising a flexible substrate;
a plurality of light emitting diodes (LEDs) deposited on said module; and
an electrostatic discharge (ESD) diode deposited on said module in proximity to said plurality of LEDs.

10. A light source according to claim 9, wherein said ESD diode is deposited using a spatial atomic layer deposition process.

11. A light source according to claim 9, wherein said ESD diode is deposited using a chemical vapor deposition process.

12. A light source according to claim 9, wherein said ESD diode is deposited using a pulsed laser deposition process.

13. A light source according to claim 9, wherein said ESD diode is deposited using a process selected from the group consisting of metalorganic chemical vapor deposition, atomic layer deposition, direct writing via positive displacement dispensing, ink-jet deposition and aerosol jetting deposition.

14. A light source according to claim 9, wherein said proximity is determined based on a requirement for ESD protection reliability.

15. A light source according to claim 9, wherein the number of said ESD diodes is determined based on a requirement for ESD protection reliability.

16. A light source according to claim 9, wherein said ESD diode comprises a conductive polymer.

17. A method of providing electro-static discharge (ESD) protection to an LED lighting module, said method comprising:
providing a printed circuit board (PCB) on a flexible substrate as a base for said LED lighting module;
depositing a plurality of LEDs in an array on said PCB; and
depositing a plurality of conductive polymer ESD diodes on said PCB in a thin film array, wherein each of said ESD diodes is deposited in proximity to one each of said LEDs.

18. A method according to claim 17, wherein said ESD diode is deposited using a spatial atomic layer deposition process.

19. A method according to claim 17, wherein said ESD diode is deposited using a chemical vapor deposition process.

20. A method according to claim 17, wherein said ESD diode is deposited using a pulsed laser deposition process.
